(19) United States
(12) Patent Application Publication
(10) Pub. No.: US 2007/0159223 A1
(43) Pub. Date: Jul. 12, 2007

(54) Phase locked loop circuit

(76) Inventors: Feng Wang, Portland, OR (US); Keng L. Wong, Portland, OR (US); Michael C. Rifani, Beaverton, OR (US)

Correspondence Address: TROP PRUNER & HU, PC, 1616 S. VOSS ROAD, SUITE 750, HOUSTON, TX, 77057-2631, US

(21) Appl. No.: 11/319,043

(22) Filed: Dec. 27, 2005

(51) Int. Cl. H03L 7/06

(52) U.S. Cl. 327/156

(57) ABSTRACT

A technique includes locking a locked loop circuit onto a reference clock signal. The locking includes locking the lock loop circuit onto the reference clock signal in response to a first feedback signal provided by a first feedback path and locking the locked loop circuit onto the reference clock signal in response to a second feedback signal that is provided by a second feedback path.

### BACKGROUND

The invention generally relates to a phase locked loop circuit.

A modem microprocessor typically includes circuitry that is clocked by a relatively high frequency clock signal. The microprocessor typically includes a phase locked loop (PLL) that generates the clock signal for the circuitry in response to a lower and externally-supplied reference clock signal.

The PLL typically includes a phase detector that compares the phase of the reference clock signal to the phase of the PLL's output clock signal for purposes of generating a signal to control a charge pump of the PLL. The charge pump, in response to the signal from the phase detector, generates a control signal, which passes through a loop filter of the PLL. The output signal from the loop filter typically controls the frequency of a voltage controlled oscillator (VCO), which provides the output clock signal for the PLL. The PLL is deemed to have locked onto the reference clock signal when the output clock signal from the PLL has a predefined phase and frequency relationship to the reference clock signal.

### BRIEF DESCRIPTION OF THE DRAWING

FIG. 1 is a schematic diagram of a clock subsystem according to an embodiment of the invention.

FIGS. 2, 3, 4, 5, 6, 7, 9, 10, 11 and 12 are waveforms of signals of a phase locked loop circuit of FIG. 1 according to an embodiment of the invention.

FIG. 8 is an exemplary waveform illustrating a two phase locking operation of the phase locked loop circuit according to an embodiment of the invention.

FIG. 13 is a simulated waveform illustrating the two phase locking operation of the phase locked loop circuit according to an embodiment of the invention.

FIG. 14 is a schematic diagram of a computer system according to an embodiment of the invention.

### DETAILED DESCRIPTION

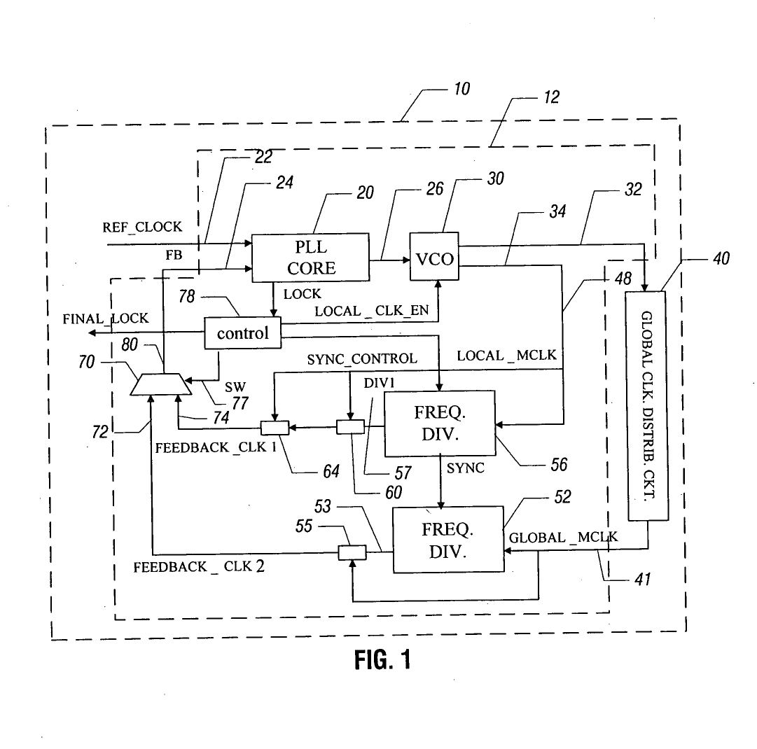

Referring to FIG. 1, a clock subsystem 10 in accordance with the various embodiments of the invention generates and distributes clock signals to various components of a system, such as a microprocessor, for example. The microprocessor may include local circuitry that is located near the subsystem 10, as well as other circuitry that is located further from the subsystem 10 and receives clock signals from a global clock distribution circuit 40. As described herein, the clock subsystem 10 receives an input clock signal from an output terminal 32 of a phase locked loop (PLL) 12 and generates various clock signals in response thereto. One of these clock signals is a clock signal called “GLOBAL_MCLK,” which is received by the PLL 12 and used in a two stage locking operation (described below) to synchronize the global clock distribution circuit 40 to a reference clock signal (called “REF_CLOCK” in FIG. 1).

The PLL 12 includes a PLL core 20 that includes such PLL components as a phase detector, charge pump and loop filter. In general, the PLL core 20 is constructed to generate a signal (called “V_{CTRL}” IN FIG. 1) at its output terminal 26 to control the frequency of a voltage controlled oscillator (VCO) 30 to lock a feedback signal (called “FB” in FIG. 1) to the core 20 to a reference clock signal (called “REF_CLOCK” in FIG. 1) so that the FB feedback signal has a predetermined phase and frequency relationship relative to the CLOCK_REF reference clock signal.

When the PLL core 20 locks onto the REF_CLOCK reference clock signal, the output clock signal from the VCO 30 has a predefined frequency and phase relationship to the REF_CLOCK reference clock signal. As a specific example, a signal that is provided by the VCO 30 may be in phase with the REF_CLOCK reference clock signal and may have a frequency that is a multiple of the frequency of the REF_CLOCK reference clock signal.

Thus, the PLL 12 may be used for purposes of synchronizing the phases and frequencies of clock signals that are provided by the global clock distribution circuit 40 to the REF_CLOCK reference clock signal.

An output signal of the VCO 30 may be routed through the global clock distribution circuit 40 for purposes of producing the FB feedback clock signal. A difficulty, however, with using the PLL 12 for purposes of synchronizing a global circuit, such as the above-mentioned global clock distribution circuit 40, is that during PLL lock acquisition, the frequency of the signal that is generated by the VCO 30 tends to have some probability of overshoot to a much higher value for a short period. Although the PLL 12 may be capable of temporarily handling such an overshoot, other circuitry, such as the global clock distribution circuit 40 may have difficulty with the higher frequencies. As a result, feedback through the global clock distribution circuit 40 may be affected or delayed to either cause failure of the lock or a relatively long lock time.

One way to accommodate the high frequencies is to provide a relatively large bandwidth through the global clock distribution circuit 40. However, such an extra high bandwidth may be either hard to achieve or consume a relatively large amount of power. Another solution might be to regulate and provide the FB feedback signal locally to the PLL core 20 and use another locked loop circuit, such as a delay locked loop (DLL), to regulate the phase for the global clock distribution circuit 40.

In accordance with embodiments of the invention, the PLL 12 locks the clock signals of the global clock distribution circuit 40 to the REF_CLOCK reference clock signal using a two stage lock-in, which, in turn, uses two feedback paths: a local feedback path that is used during an initial lock-in stage for purposes of locking the PLL 12 onto the frequency of the REF_CLOCK reference clock signal; and a global feedback path through the global clock distribution circuit 40 during a subsequent lock-in stage for purposes of subsequently locking the phases of the clock signals of the global clock distribution circuit 40 to the REF_CLOCK reference clock signal.

Thus, the PLL 12 locks twice to reach the final lock: the first lock of the PLL 20 produces the FB feedback clock from a shorter and “tighter” local feedback path to lock the PLL 20 to the frequency of the REF_CLOCK reference clock signal; and the second lock uses a global feedback path to lock the phase of the globally-produced clock signal to the phase of the REF_CLOCK reference clock signal to produce the final lock-in for the PLL 20. Thus, if the global feedback path is provided by the global clock distribution circuit 40, the above-described two lock-ins may be used to synchronize the phase and frequency of the clock signals that are provided by the circuit 40 onto the REF_CLOCK reference clock signal without requiring a separate DLL/PLL or a high bandwidth for the circuit 40.

In accordance with some embodiments of the invention, the VCO 30 generates two clock signals at output terminals 32 and 34, respectively. The output clock signal 32 provides the GLOBAL_MCLK clock signal to the global feedback path; and the clock signal that a local clock signal (called “LOCAL_MCLK” in FIG. 1) is provided by the output terminal 34 by the local feedback path.

As shown in FIG. 1, in some embodiments of the invention, both the global and local feedback paths include frequency dividers. In this regard, a frequency divider 56 receives the LOCAL_MCLK clock signal to produce a divided frequency output clock signal at an output terminal 57 of the divider 56; and a frequency divider 52 receives the GLOBAL_MCLK clock signal to produce a frequency divided clock signal at an output terminal 53 of the divider 52.

In accordance with some embodiments of the invention, the frequency divided signals that appear at the output terminals 57 and 53 of the frequency dividers 56 and 52, respectively, pass through feedforward delay compensation circuits. More specifically, the output signal from the output terminal 57 of the frequency divider 56 passes through feedforward compensation circuit 60 and 64 to produce a clock signal called “FEEDBACK_CLK1.” The frequency divided signal that is provided at the output terminal 53 of the frequency divider 52 passes through a feedforward compensation circuit 55 that introduces a delay to the signal to produce a corresponding clock signal called “FEEDBACK_CLK2.”

A switch, or multiplexer 70, selects which of clock signals (i.e., either FEEDBACK_CLK1 or the FEEDBACK_CLK2 signal) is used to generate the FB feedback signal that is received at the feedback terminal 54 of the PLL core 20. More specifically, the multiplexer 70 includes an input terminal 74 that receives the FEEDBACK_CLK1 clock signal and an input terminal 72 that receives the FEEDBACK_CLK2 clock signal. A control terminal 77 of the multiplexer 70 receives a switch control signal (called “SW” in FIG. 1) for purposes of selectively routing either the FEEDBACK_CLK1 or the FEEDBACK_CLK2 clock signal to an output terminal 80 of the multiplexer 70, a terminal that provides the FB feedback signal. Thus, during the initial lock-in stage, the multiplexer 70 selects the FEEDBACK_CLK1 clock signal from the local feedback path; and during the subsequent lock-in stage, the multiplexer 70 selects the FEEDBACK_CLK2 clock signal to be the FB feedback signal.

In accordance with some embodiments of the invention, the frequency divider 56 provides a synchronization signal (called “SYNC,” in FIG. 1) that is received by the frequency divider 52 for purposes of synchronizing the divider 52 at the beginning of the second lock-in-stage. More specifically, in response to the PLL core 20 locking onto the FB feedback signal during the first lock-in stage, the frequency divider 56 asserts (drives high, for example) the SYNC signal to synchronize the frequency divider 52. After the PLL 20 declares the first lock, the local feedback path, including the frequency divider 56, may be turned off, in some embodiments of the invention, for purposes of conserving power.

Among the other features of the PLL 12, in accordance with some embodiments of the invention, the PLL core 20 provides a signal called “LOCK,” that is asserted (driven high, for example) for purposes of indicating when the PLL 20 has achieved a lock. The lock signal may be received by the control circuit 78 for purposes of determining when to assert the SW signal to change the FB feedback signal to reflect the FEEDBACK_CLK2 clock signal. The control circuit 78 may provide a local clock enable signal (called “LOCAL_CLK_EN,” in FIG. 1) that is received by the VCO 30. In response to the control circuit 78 asserting (driving high, for example) the LOCAL_CLK_EN signal, the VCO 30 provides an output clock signal to the local feedback path output terminal 34 in accordance with some embodiments of the invention. Conversely, in response to the LOCAL_CLK_EN signal being de-asserted (driven low, for example), the VCO 30 provides an output clock signal to its output terminal 32 for the long loop circuit 40. Additionally, in accordance with some embodiments of the invention, the control circuit 78 provides a synchronization control signal (called “SYNC_CONTROL,” in FIG. 1) that is de-asserted by the control circuit 78 to indicate when the first lock has been achieved.

As mentioned above, the local feedback path includes two feedforward compensation circuit 60 and 64, as compared to the single feedforward compensation circuit 55 of the global feedback path. This is due to the recognition that the clock signal that is provided at the output terminal 57 of the frequency divider 56 may be later than the clock signal that is provided at the output terminal 53 of the frequency divider 52 by as much as one clock period. This is caused by the uncertainty in the phase relationship between the two feedback clocks. Therefore, in accordance with some embodiments of the invention, an extra clock period is added to the clock signal that is produced by the frequency divider 56 to ensure that the FEEDBACK_CLK1 clock signal is always earlier than the FEEDBACK_CLK2 clock signal. Due to the result of the first lock, the FEEDBACK_CLK1 signal is in phase with the reference clock. At the time of the first lock, the FEEDBACK_CLK2 signal is always slightly earlier in phase than the REF_CLOCK reference clock signal.

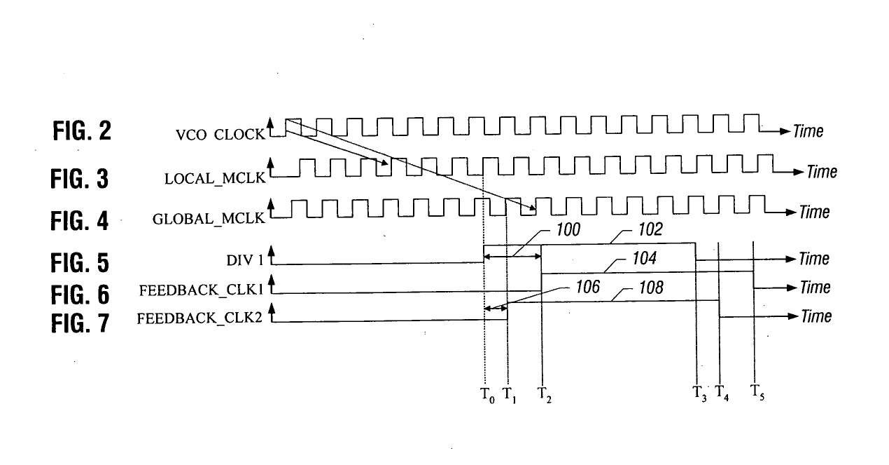

FIGS. 2-7 are waveforms, which illustrate operation of the PLL 12 in accordance with some embodiments of the invention. FIG. 2 depicts a waveform (called “VCO_CLOCK”) that represents the clock signal that is provided by the VCO 30 to either the output terminal 32 or the output terminal 34, depending on whether the PLL 20 is in the first lock-in stage or is operating after the first lock. The VCO_CLOCK signal produces the LOCAL_MCLK clock signal that is depicted for purposes of example in FIG. 3 and the GLOBAL_MCLK clock signal that is depicted in FIG. 4 for purposes of example. As depicted in FIGS. 3 and 4, the LOCAL_MCLK clock signal lags the GLOBAL_MCLK signal by an offset 106. However, due to the above-described delays that are applied to the local feedback path, the FEEDBACK_CLK1 clock signal (depicted in FIG. 6) lags the FEEDBACK_CLK2 clock signal (depicted in FIG. 7) by a predefined number (called “M”) of clock periods. More specifically, the frequency divider 56 produces the DIV1 clock signal at its output terminal 57, a signal that is depicted in FIG. 5. The delay 100 is provided by the feedforward composition in the local feedback path to produce the corresponding FEEDBACK_CLK1 clock signal.

Thus, to summarize, in the example shown in FIGS. 2-7, at time T₀, the DIV1 clock signal from the frequency divider 76 has a rising edge, an edge that precedes a corresponding rising edge of the FEEDBACK_CLK2 signal at time T₁. However, due to the delay 100, the corresponding rising edge of the FEEDBACK_CLK1 signal is at time T₂. Likewise, although the DIV1 signal has a falling edge at time T₃, the corresponding falling edge of the FEEDBACK_CLK1 signal is at time T₅, a time after the falling edge of the FEEDBACK_CLK2 signal, which occurs at time T₄.

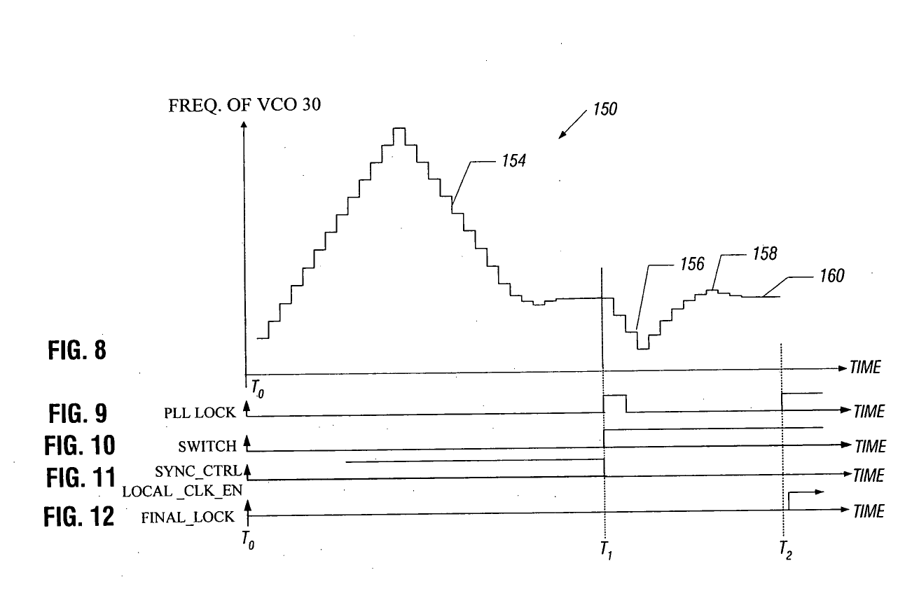

FIG. 8 depicts a simulated waveform 150, which illustrates the frequency response of the PLL 12 over both stages of the locking sequence. During the first lock-in stage, there may be significant overshoot, as depicted in the portion 154 of the frequency response 150. However, the overshoot is not a consistent event. The degree of overshoot depends on the total accumulated phase error at the point of frequency lock crossing. If the total phase error is approaching the whole reference clock period, the worst case overshoot is triggered. The local loop feedback path may be designed to tolerate this periodic excursion of the high frequency after the switch between the first lock-in stage and the second lock-in stage at time T₁. As shown, at the beginning of the second lock-in stage, the PLL 12 may undergo an undershoot, as depicted at reference numeral 156, due to the established phase relationship between the global feedback path and the REF_CLOCK reference clock signal. This undershoot magnitude is significantly smaller than the first overshoot, because the phase error is within one to two cycles of the higher frequency clock signal instead of a whole reference clock cycle of the REF_CLOCK reference clock signal. Although a subsequent overshoot (depicted at reference numeral 158) may occur, the magnitude of the subsequent overshoot is negligible because of the damping of the PLL system. Overall, the overshoot when locking using the global feedback path is significantly reduced, as compared to a PLL system that does not use the two lock intervals that are described herein. As shown in FIG. 8, near time T₂, the PLL 12 achieves a lock as indicated by a constant portion 160 of the waveform 150.

FIGS. 9, 10, 11 and 12 depict the PLL_LOCK, SW, SYNC_CTRL, the LOCK_CLK_EN and FINAL_LOCK signals, respectively. Referring to FIG. 1 in conjunction with FIGS. 9, 10, 11 and 12, at time T₀, the PLL_LOCK signal is de-asserted (driven low) to cause the local feedback path to provide the FB feedback signal. At time T₁, the PLL core 20 pulses the PLL_LOCK signal high to indicate a lock-in to the FB feedback signal. In response to this occurrence, the control circuit 78 asserts (drives high) the SW signal to switch the FB feedback clock signal to the global feedback path. Also, in response to the assertion of the PLL_LOCK signal, the control circuit 78 de-asserts (drives low) the SYNC_CTRL signal and de-asserts the LOCAL_CLK_EN clock signal. At time T₂, the PLL core 20 locks onto the FB feedback signal again, which causes the PLL core 20 to subsequently re-assert the PLL_LOCK signal. In response to the subsequent assertion of the PLL_LOCK signal, the control circuit 78 asserts the FINAL_LOCK signal to indicate final locking in of the PLL 12.

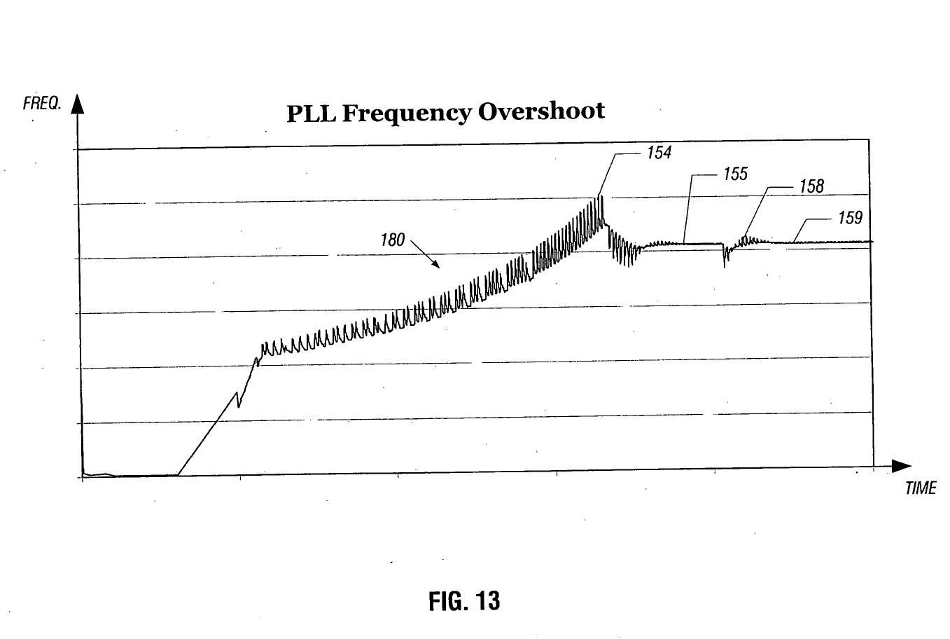

FIG. 13 depicts a waveform 180 of the frequency of the PLL 12 in accordance with an embodiment of the invention. The waveform 180 of FIG. 13 represents the same frequency response as the waveform 150 of FIG. 8, but the waveform 180 is expanded in time. Referring to FIG. 13, in locking in to the frequency of the locally-provided feedback signal, the PLL 12 undergoes the overshoot 154. Although not depicted in FIG. 13, the overshoot 154 may be quite large; and the two stage lock-in technique that is described herein prevents subjecting the global clock distribution circuit to a large overshoot 154. After undergoing the overshoot 154, the PLL 12 locks onto the locally-provided feedback signal in the first lock-in stage, as depicted at reference numeral 155. During the subsequent lock-in stage to the globally-provided feedback signal, the PLL 12 undergoes the slight undershoot 156 and overshoot 158 before the final lock-in, depicted at reference numeral 159.

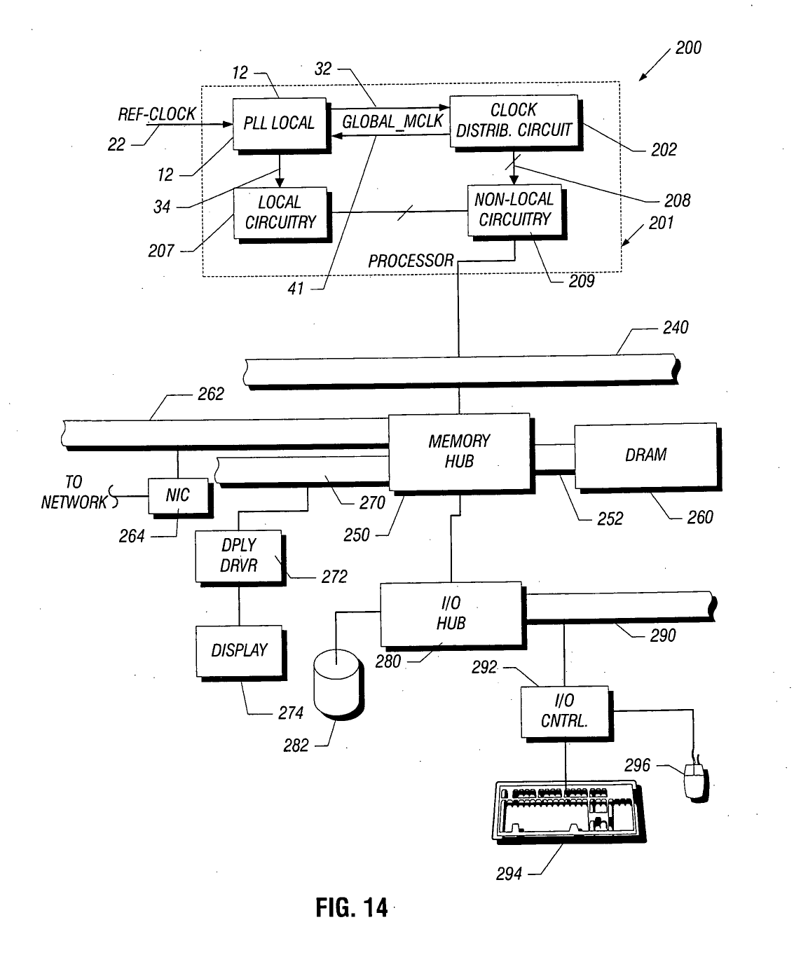

Referring to FIG. 14, in accordance with some embodiments of the invention, the PLL 12 may be part of a processor 201 (a microprocessor, for example), and the PLL circuit 12 may be coupled to a global clock distribution circuit 202 of the processor 201. Thus, the PLL 12 may, via the output terminal 34, provide a clock signal to local circuitry 207 of the processor 201; and the clock distribution circuit 202 may include output terminals 208 that provide clock signals to global, or non-local circuitry 209 of the processor 201.

The processor 201 may be part of a computer system 200, in accordance with some embodiments of the invention. In addition to the processor 201, the computer system 200 may include, for example, a north bridge, or memory hub 250. The memory hub 250 and the processor 201 may be coupled to a system bus 240. The memory hub 250 may provide communication between the system bus 240 and an Accelerated Graphics Port (AGP) bus 262 and Peripheral Component Interconnect (PCI) bus 270. The AGP is described in detail in the Accelerated Graphics Port Interface Specification, Revision 1.0, published on Jul. 31, 1996, by Intel Corporation of Santa Clara, Calif. The PCI Specification is available from The PCI Special Interest Group, Portland, Oreg. 97214.

Devices such as a network interface card (NIC) 264 may be coupled to the PCI bus 262 for purposes of coupling the computer system 200 to a network. Devices such as a display driver 272 (that drives a display 274) may be coupled to the bus 270. The memory hub 250 may also be coupled to a memory bus 252 that establishes communication between the memory hub 250 and a system memory, such as a dynamic random access memory (DRAM) 26, for example.

In accordance with some embodiments of the invention, the memory hub 250 may be coupled to another bridge, such as a south bridge, or input/output (I/O) hub 280. Among its various functions, the I/O hub 280 may control a disk drive 282 and may be in communication with an I/O bus 290. An I/O controller 292 may be coupled to the I/O bus 290 and receive input from such devices as a mouse 296 and a keyboard 294.

It is noted that FIG. 14 is shown merely for purposes of an example, as different computer architectures and systems that use the processor 201 and/or the PLL 12, are within the scope of the appended claims.

While the invention has been disclosed with respect to a limited number of embodiments, those skilled in the art, having the benefit of this disclosure, will appreciate numerous modifications and variations therefrom. It is intended that the appended claims cover all such modifications and variations as fall within the true spirit and scope of the invention.

What is claimed is:

1. A method comprising:
locking a locked loop circuit onto a reference clock signal, including locking the locked loop circuit onto the reference clock signal in response to a first feedback signal provided by a first feedback path and locking the locked loop circuit onto the reference clock signal in response to a second feedback signal provided by a second feedback path.

2. The method of claim 1, wherein the acts of locking the locked loop circuit onto the reference clock signal in response to the first feedback signal and locking the locked loop circuit onto the reference clock signal in response to the second feedback signal occur in a time sequence.

3. The method of claim 1, wherein the act of locking the locked loop circuit onto the reference clock signal in response to the first feedback signal occurs before the act of locking the locked loop circuit onto the reference clock signal in response to the second feedback signal.

4. The method of claim 3, wherein the act of locking the locked loop circuit onto the reference clock signal in response to the second feedback signal comprises routing an output signal of the locked loop circuit through a clock distribution circuit.

5. The method of claim 1, wherein the first feedback path introduces more signal delay than the second feedback path.

6. The method of claim 1, further comprising:
providing an output signal of the locked loop circuit to a clock distribution circuit.

7. The method of claim 1, wherein the act of locking the locked loop circuit onto the reference clock signal in response to the first feedback signal comprises routing an output signal of the locked loop circuit through a frequency divider.

8. The method of claim 1, further comprising:
using the locked loop circuit to generate an output signal, the output signal having a higher frequency than the reference clock signal.

9. An apparatus comprising:
a locked loop circuit to provide an output signal in response to a signal received at an input terminal of the locked loop circuit and a reference signal; and
a switch to provide a first feedback signal provided by a first feedback path to the input terminal to cause the locked loop circuit to lock onto the reference signal and provide a second feedback signal provided by a second feedback path to the input terminal to cause the locked loop circuit to lock onto the reference signal.

10. The apparatus of claim 9, wherein the switch provides the feedback signal and the second feedback signal to the input terminal in a sequence.

11. The apparatus of claim 10, wherein the switch:
first provides the first feedback signal to the input terminal, and
subsequently, in response to the locked loop circuit locking onto the reference signal in response to the first feedback signal, remove the first feedback signal from the input terminal and provide the second feedback signal to the input terminal.

12. The apparatus of claim 9, wherein the second feedback path comprises a clock distribution network.

13. The apparatus of claim 9, wherein the first feedback path introduces more signal delay than the second feedback path.

14. The apparatus of claim 9, wherein the locked loop circuit comprises a phase locked loop.

15. The apparatus of claim 9, further comprising:
at least one frequency divider located in at least one of the first feedback path and the second feedback path.

16. The apparatus of claim 9, wherein the output signal has a higher frequency than the reference clock signal.

17. A system comprising:
a dynamic random access memory; and
a microprocessor coupled to the dynamic random access memory, the microprocessor comprising:
a locked loop circuit to provide an output signal in response to a signal received at an input terminal of the locked loop circuit and a reference signal; and
a switch to provide a first feedback signal provided by a first feedback path to the input terminal to cause the locked loop circuit to lock onto the reference signal and provide a second feedback signal provided by a second feedback path to the input terminal to cause the locked loop circuit to lock onto the reference signal.

18. The system of claim 17, wherein the microprocessor further comprises:
a microprocessor core to receive the output signal.

19. The system of claim 17, wherein the second feedback path comprises a clock distribution of the microprocessor.

20. The system of claim 17, wherein the switch provides the feedback signal and the second feedback signal to the input terminal in a sequence.

22. The system of claim 17, wherein
the switch first provides the first feedback signal to the input terminal, and
subsequently, in response to the locked loop circuit locking onto the reference signal in response to the first feedback signal, the switch removes the first feedback signal from the input terminal and provides the second feedback signal to the input terminal.
